(19) United States
(12) Patent Application Publication
(10) Pub. No.: US 2007/0287294 A1
(43) Pub. Date: Dec. 13, 2007

(54) Interconnect structures and methods for fabricating the same

(75) Inventors: Ting-Chu Ko, Hsinchu (TW); Ming-Hsing Tsai, Chu-Pei (TW); Shau-Lin Shue, Hsinchu (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/448,713

(22) Filed: Jun. 8, 2006

(51) Int. Cl. H01L 21/302; H01L 21/31

(52) U.S. Cl. 438/704; 438/758; 257/E21.641

(57) ABSTRACT

Methods for fabricating interconnect structures are provided. An exemplary method for fabricating an interconnect comprises providing a substrate with a first dielectric layer thereon. At least one conductive feature is formed in the first dielectric layer. A conductive cap is selectively formed to overlie the conductive feature. A surface treatment is performed on the first dielectric layer and the conductive cap. A second dielectric layer is then formed to overlie the first dielectric layer.

### BACKGROUND

The present invention relates to a semiconductor device, and in particular to an interconnect structure having selective cap with improved adhesion therein.

In ultra large-scale integrated (ULSI) circuit manufacturing, semiconductor devices are fabricated on a substrate or a silicon wafer. After the formation of the devices, metal lines for interconnection are defined using a metallization process. As the integration of circuits increases, manufacturing with high yield and highly reliable metal interconnect lines is difficult to achieve. A method of fabricating a damascene structure etches trenches for metal interconnect lines and then fills the trenches with metal, such as copper. Chemical mechanical polishing (CMP) is used to polish the metal material. This method offers improved fabrication of a submicron VLSI interconnection with high performance and high reliability.

Nevertheless, the utilization of copper introduces additional problems. For example, when copper is utilized, copper must be encapsulated from the surrounding interlayer dielectric, since copper diffuses easily into the adjacent dielectrics and may significantly degrade a device's performance when it reaches the semiconductor substrate.

Therefore, a conformal barrier layer is utilized and formed within the damascene structure prior to copper filling to prevent copper diffusion. In addition, a top seal layer is also utilized and formed over the damascene structure filled with copper to thereby encapsulate the copper and prevent copper diffusing in a sequentially formed dielectric layer. However, adhesion between the top seal layer and the copper is somehow problematic and reliability performances of such a damascene structure is therefore affected.

### SUMMARY

Interconnect structures and methods for fabricating are provided. An exemplary embodiment of a method for fabricating an interconnect comprises providing a substrate with a first dielectric layer thereon. At least one conductive feature is formed in the first dielectric layer. A conductive cap is selectively formed to overlie the conductive feature. A surface treatment is performed on the first dielectric layer and the conductive cap. A second dielectric layer is then formed to overlie the first dielectric layer.

An exemplary embodiment of a method for improving adhesion between low-k dielectric layers comprises providing a first low-k dielectric layer with a conductive feature therein. A conductive cap is selective formed over the conductive feature. A surface treatment is performed on the first low-k dielectric layer and the conductive cap. A second low-k dielectric layer is provided over the first dielectric layer and the conductive cap.

An exemplary embodiment of an interconnect structure comprises a substrate. A first dielectric layer with at least one conductive feature formed thereon overlies the substrate. A cap layer overlies the conductive feature. A second dielectric layer overlies the first dielectric-layer and the conductive cap, wherein a region of about 20-1000 Åbelow a top surface of the dielectric layer and the conductive feature has a nitrogen concentration of 10¹⁵-10²¹ atoms/cm².

A detailed description is given in the following embodiments with reference to the accompanying drawings.

### BRIEF DESCRIPTION OF THE DRAWINGS

The invention can be more fully understood by reading the subsequent detailed description and examples with reference made to the accompanying drawings, wherein:

FIGS. 1-7 are cross sections illustrating steps of a method for fabricating an interconnect structure, according to an embodiment of the invention.

### DESCRIPTION

Methods for fabricating interconnect structures will be described here in greater detail. Some embodiments of the invention, such as the exemplary embodiments described, can potentially enhance adhesion between a cap layer, a underlying interconnect feature and an overlying dielectric layer, and improve reliability of a semiconductor device including such interconnect structure. In some embodiments, this can be accomplished by performing a surface treatment to the interconnect feature using nitrogen-containing gases or species before formation of a subsequent dielectric layer formed over it.

In this specification, expressions such as “overlying the substrate”, “above the layer”, or “on the film” simply denote a relative positional relationship with respect to the surface of the base layer, regardless of the existence of intermediate layers. Accordingly, these expressions may indicate not only the direct contact of layers, but also, a non-contact state of one or more layers. By use of the term “low dielectric constant” or “low-k” herein, is meant a dielectric constant (k) less than the dielectric constant of a conventional silicon oxide. Preferably, the low-k dielectric constant of is less than about 4.0.

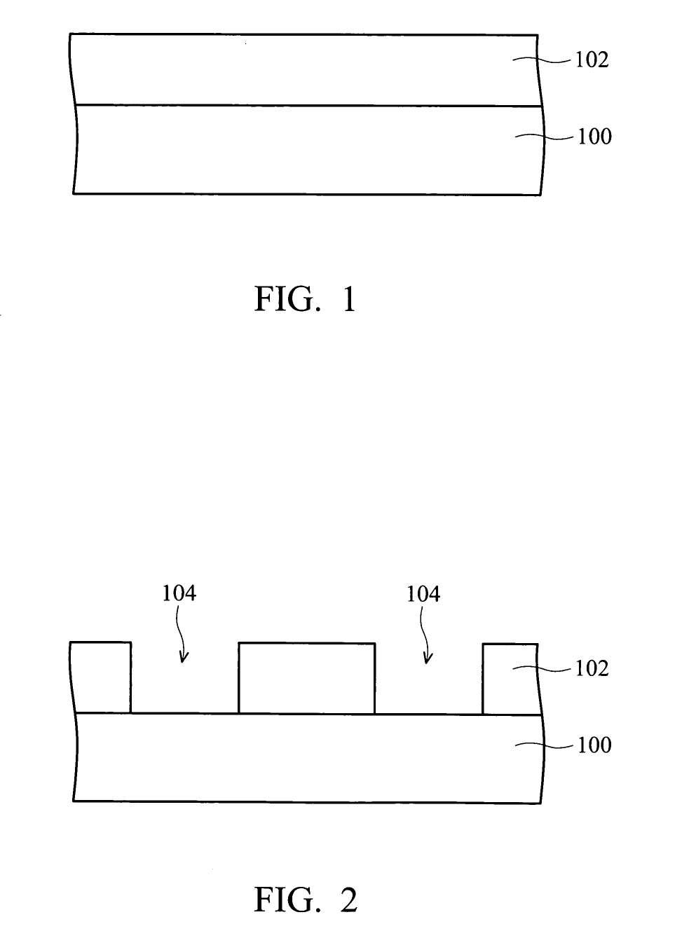

Referring now to the drawings, methods for forming an interconnect structure are now described with reference to FIGS. 1-7. FIG. 1 shows a cross-sectional view of a semiconductor substrate 100 having a number of layer deposited thereon for the formation of wiring lines. The substrate may contain a variety of elements, including, for example, transistors, diodes, and other semiconductor elements (not shown) as are well known in the art. The substrate 100 may also contain other metal interconnect layers. A first dielectric layer 102 is deposited overlying the substrate 100 where the interconnect structure is to be formed. The first dielectric layer 102 may consist of one or more commonly used dielectric materials in semiconductor processing. For example, the first dielectric layer 102 may be silicon dioxide, borophosphosilicate glass (BPSG), phosphosilicate glass (PSG), or low-k materials such as fluorosilicate glass (FSG). Preferably, the first dielectric layer 102 comprises low-k materials and has a thickness of 10 to 1000 Å.

Referring to FIG. 2, the first dielectric layer 102 is etched through a photoresist mask which is not shown. This etching step forms interconnect trenches 104 in the first dielectric layer 102. The interconnect trenches are etched by a conventional reactive-ion etching (RIE) procedure. In this embodiment, selective protection layers are intended to form on an interconnect structure in a single damascene process. It will be understood by those skilled in the art that the invention could be applied to a dual damascene process. In such cases, interconnect holes are formed inside the interconnect trenches 104 for contact between the interconnects and some other layer.

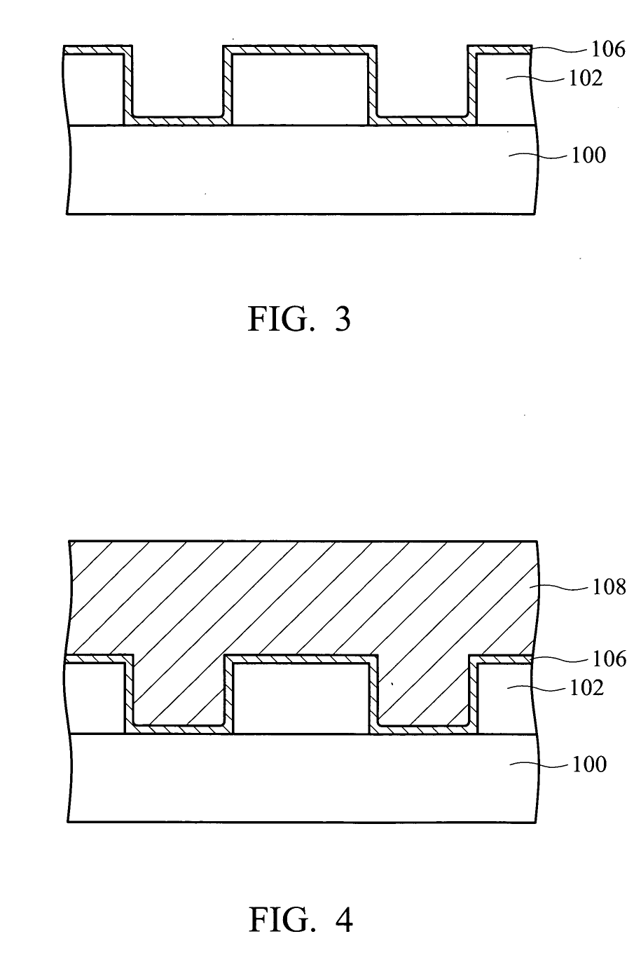

Referring now to FIG. 3, a barrier layer 106 is deposited overlying the first dielectric layer 202 and lining the interconnect trenches 104. The purpose of the barrier layer 106 is to prevent oxidation and diffusion of the subsequently deposited copper metal layer. The barrier layer 206 may be composed of any of several metals such as tantalum (Ta), titanium (Ti), or tungsten (W), or nitrides such as titanium nitride (TiN), tantalum nitride (TaN), and tungsten nitride (WN). The barrier layer 106 is deposited to a thickness ranging from about 5 to 2000 Å.

Referring to FIG. 4, a metal layer 108, such as a copper layer, is deposited overlying the barrier layer 106 and filling the interconnect trenches 104. Typically, a seed layer must first be deposited using physical vapor deposition (PVD) or chemical vapor deposition (CVD) for forming a subsequent copper layer. The metal layer 208 is then deposited by, for example, electrochemical plating over the seed layer. The metal layer 108 is deposited at a thickness of about 5 to 2500 Å.

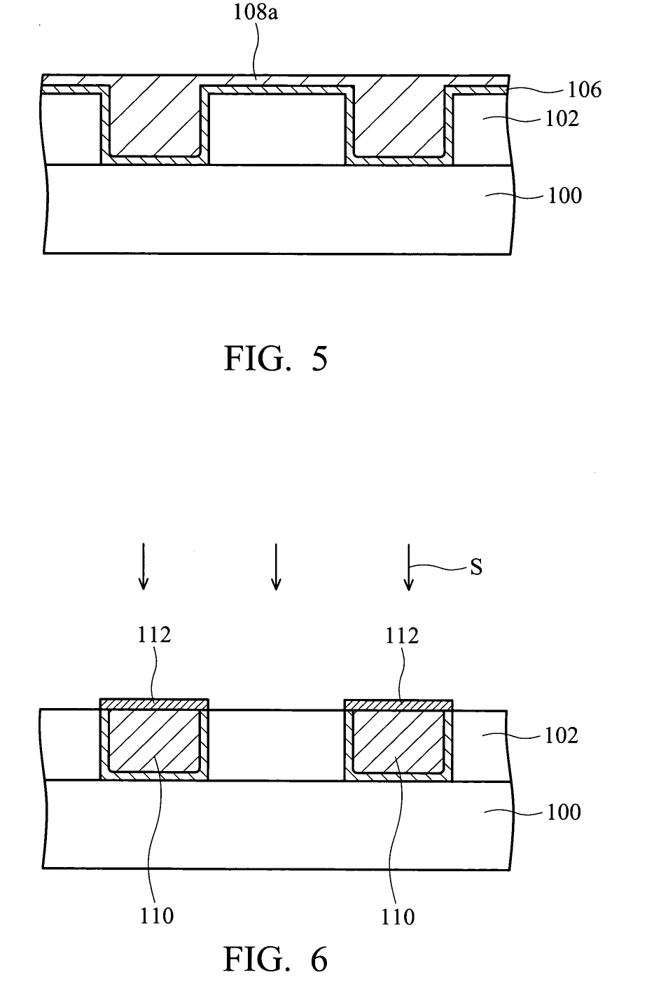

Referring now to FIG. 5, the metal layer 108 is partially polished back using a conventional chemical-mechanical polishing (CMP) process to remove most of the undesired copper. Ideally, the barrier layer 106 is not polished in this step and remains covered by the remaining metal layer 108a.

Next, referring to FIG. 6, the remaining metal layer 108a and the barrier layer 106 are polished down to the top surface of the first dielectric layer 102 to thereby define metal interconnects 110. The described polishing leaves the first dielectric layer 102 and the metal interconnects 110. A cap layer 112 is then selectively formed over the metal interconnects 110, encapsulating the top surface thereof. The cap layer 112 can be selectively formed by electroless plating at a thickness of about 10-2000 Å and may comprise material such as cobalt tungsten phosphide (CoWP) or cobalt tungsten boride (CoWB). The cap layer 112 can function as a sealing layer to prevent copper diffusion and oxidation for the following fabrication.

Still referring to FIG. 6, a surface treatment S is then performed on the substrate 100. The surface treatment S can be thermal annealing or ion implantation using nitrogen-containing gases or species. When the surface treatment S is performed as thermal annealing, the substrate 100 may be subject to a nitrogen-containing atmosphere using reactants such as nitrogen (N₂), nitrogen oxide (NO) or ammonia (NH₃) at a temperature of about 25-500° C. for about 0.3-60 seconds. When the surface treatment S using ion implantation, the substrate 100 may be implanted by nitrogen-containing species at an energy of about 0.1-300 KeV. After the surface treatment S, a nitrogen atoms with a dosage of about 10¹⁵-10²¹ atoms/cm³ can thus be examined in a region of about 20-1000 Å below the surface of the first intermetal dielectric layer 102 and the metal interconnects 110 by, for example, secondary neutral mass spectrometry (SIMS) examination. For comparison, the first dielectric layer 102 and the copper interconnects 110 without such surface treatment S typically has a nitrogen concentration less than about 10¹⁵ atoms/cm³.

Moreover, the above surface treatment S can be a plasma treatment using plasmas having nitrogen-containing species. When the surface treatment S is performed as plasma treating, the substrate 100 may be subject to a plasma having nitrogen-containing species such as nitrogen (N₂) or ammonia (NH₃) at a electric field intensity of about 0.1-50 V/cm² and a pressure of about 10⁻⁸˜10 torr. for about 0.1˜60 seconds.

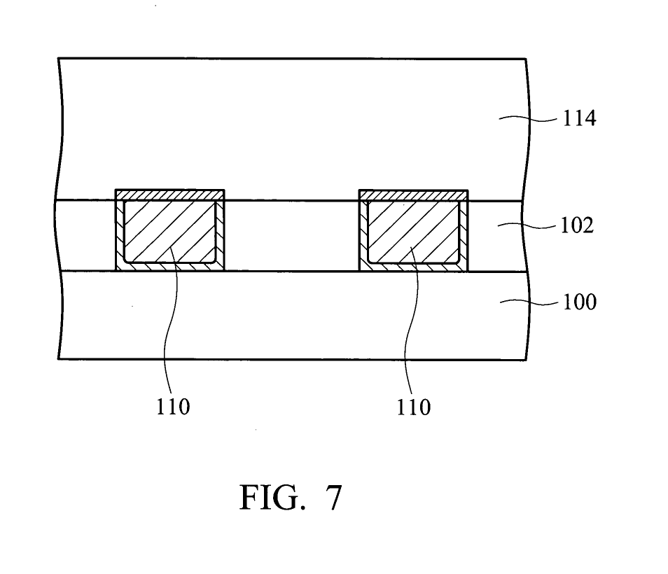

Thus, referring to FIG. 7, a second dielectric layer 114 can be directly deposited on the cap layers 112 and the first dielectric layer 102 without a conventional sealing layer of silicon nitride. Due to the surface treatment S performed on the substrate 100, adhesion between the second dielectric layer 114. For example, the second dielectric layer 114 may be silicon dioxide, borophosphosilicate glass (BPSG), phosphosilicate glass (PSG), or low-k materials such as fluorosilicate glass (FSG). Preferably, the second dielectric layer 114 comprises low-k materials and has a thickness of 10 to 10000 Å.

Adhesion between the metal interconnects 110, the first intermetal dielectric layer 102, and the cap layer 112 are can thus be improved by the surface treatment S and and shows a reliable electrical performance.

Table 1 shows an electro-migration (EM) tests of interconnect structures having selective formed conductive caps with or without the described surface treatment S. A interconnect structure with conductive vias of a feature size of about 0.1˜0.18 μm was tested under 300° C. The conductive vias have an initial resistance of about 450-500 Ω.

TABLE 1

| | Selectively | |
|---|---|---|
| | formed cap but | Selectively |
| | without | formed cap and |
| Cap layer/ | surface | with surface |
| treatment | treatment S | treatment S |
| Jstress(A/cm²) | 2.0E+06 | 2.0E+06 |
| Test temp. (° C.) | 300 | 300 |
| Ri (Ω) | 458.1 | 492.4 |
| T₅₀ (hr) | 3.00 | 66.73 |
| T_{0.1} (hr) | 0.67 | 14.77 |
| Jmax (A/cm²) | 2.87E+05 | 1.35E+06 |

As shown by the test results in Table 1, an interconnect structure incorporating a selectively formed cap layer and a surface treatment of the invention provides improved device reliability due to the adhesion between the sealing layer, the metal layer and the adjacent dielectric layers has been improved by the surface treatment. Therefore, electro-migration resistance of copper vias and adhesion between the conductive feature and the adjacent dielectric layers are both improved. Thus, the reliability of the semiconductor device having such interconnect structures can also be improved.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for fabricating an interconnect structure, comprising:
providing a substrate with a first dielectric layer thereon;
forming at least one conductive feature in the first dielectric layer;
selectively forming a conductive cap overlying the conductive feature;
performing a surface treatment on the first dielectric layer and the conductive cap; and
forming a second dielectric layer overlying the first dielectric layer.

2. The method of claim 1, wherein the conductive cap is formed by electroless plating.

3. The method of claim 1, wherein the conductive cap comprises cobalt tungsten phosphide (CoWP) or cobalt tungsten boride (CoWB).

4. The method of claim 1, wherein the conductive features comprises copper.

5. The method of claim 1, wherein the surface treatment is performed by thermal annealing or ion implantation.

6. The method of claim 5, wherein thermal annealing is performed under a nitrogen-containing atmosphere at a temperature of about 25-500° C. for about 0.3-60 seconds.

7. The method of claim 6, wherein the nitrogen-containing atmosphere comprises nitrogen (N₂), nitrogen oxide (NO) or ammonia (NH₃).

8. The method of claim 5, wherein the ion implantation is performed with a nitrogen-containing specie at energy of about 0.1-300 KeV.

9. The method of claim 1, after the surface treatment, a nitrogen atom concentration with a dosage of 10¹⁵-10²¹ atoms/cm³ is examined within a region of about 20-1000 Å below the surface of the first dielectric layer and the conductive feature.

10. An interconnect structure formed by the method of claim 1, comprising:
a first dielectric layer with at least one conductive feature formed thereon;
a conductive cap overlying the conductive feature; and
a second dielectric layer overlying the first dielectric layer and the conductive cap, wherein a region of about 20-1000 Å below a top surface of the first dielectric layer and the conductive feature has a nitrogen concentration of 10¹⁵-10²¹ atoms/cm².

11. A method for improving adhesion between low-k dielectric layers, comprising:
providing a first low-k dielectric layer with a conductive feature therein;
selectively forming a conductive cap over the conductive feature; and
performing a surface treatment on the first low-k dielectric layer and the conductive cap; and
providing a second low-k dielectric layer over the first dielectric layer and the cap layer.

12. The method of claim 11, wherein the first and second dielectric layers comprise fluorosilicate glass (FSG).

13. The method of claim 11, wherein the conductive cap is formed by electroless plating.

14. The method of claim 11, wherein the conductive cap comprises cobalt tungsten phosphide (CoWP) or cobalt tungsten boride (CoWB).

15. The method of claim 11, wherein the conductive features comprises copper.

16. The method of claim 11, wherein the surface treatment is performed by thermal annealing or ion implantation.

17. The method of claim 16, wherein thermal annealing is performed under a nitrogen-containing atmosphere at a temperature of about 25-500° C. for about 0.3-60 seconds.

18. The method of claim 17, wherein nitrogen-containing atmosphere comprises nitrogen (N₂), nitrogen oxide (NO) or ammonia (NH₃).

19. The method of claim 16, wherein the ion implantation is performed with nitrogen-containing species at energy of about 0.1-300 KeV.

20. The method of claim 11, after the surface treatment, a nitrogen atom concentration with a dosage of 10¹⁵-10²¹ atoms/cm³ is examined within a region of about 20-1000 Å below the surface of the first dielectric layer 202 and the conductive feature.
